(19) United States
(12) Patent Application Publication
(10) Pub. No.: US 2012/0248437 A1
(43) Pub. Date: Oct. 4, 2012

(54) Semiconductor Device And Test Method For Semiconductor Device

(75) Inventors: Jong-Hyun Lee, Suwon-si (KR); Ki-Heung Park, Hwaseong-si (KR)

(73) Assignee: SAMSUNG ELECTRONICS CO., LTD., Suwon-si (KR)

(21) Appl. No.: 13/176,855

(22) Filed: Jul. 6, 2011

(30) Foreign Application Priority Data
Mar. 31, 2011 (KR) 10-2011-0029724

(51) Int. Cl. H01L 23/52

(52) U.S. Cl. 257/48; 257/E23.141

(57) ABSTRACT

A semiconductor device includes a first metal pattern formed on a first metal level. The first metal pattern has a ‘U’ shaped first curved portion. A second metal pattern is formed on the first metal level. The second metal pattern has a ‘U’ shaped second curved portion facing the first curved portion. A via structure is electrically connected to one of the first metal pattern and the second metal pattern. A third metal pattern is formed on a second metal level different from the first metal level and electrically connected to the via structure.

### CROSS-REFERENCE TO RELATED APPLICATION

This application claims priority from Korean Patent. Application No. 10-2011-0029724, filed on Mar. 31, 2011 in the Korean intellectual Property Office, and all the benefits accruing therefrom under 35 U.S.C. 119, the contents of which in its entirety are herein incorporated by reference.

### BACKGROUND

1. Field

Example embodiments relate to a semiconductor device and/or a test method for the semiconductor device.

2. Description of the Related Art

A backend process in the manufacture of semiconductors includes a metal wiring process and a via process. That is to say, a via is formed to connect a lower metal wiring and an upper metal wiring to each other.

The metal wiring process and the via process may involve short-circuiting between lower metal wirings or erroneous connection of a lower metal wiring and an upper metal wiring, due to various defects encountered during the manufacturing process, including contaminant penetration, processing errors, or the like. The defects may lower the production yield of semiconductors while increasing the manufacturing cost.

### SUMMARY

Some example embodiments provide a semiconductor device and/or a test method of a semiconductor device which can detect a defect accurately within a short time. These and other objects of the present inventive concepts will be described in or be apparent from the following description of example embodiments.

According to an example embodiment, a semiconductor device includes a first metal pattern formed on a first metal level. The first metal pattern has a ‘U’ shaped first curved portion. A second metal pattern is formed on the first metal level, the second metal pattern having a ‘U’ shaped second curved portion facing the first curved portion. A via structure is electrically connected to one of the first metal pattern and the second metal pattern. A third metal pattern is formed on a second metal level different from the first metal level and electrically connected to the via structure.

According to another example embodiment, a semiconductor device includes first and second metal patterns formed on a first metal level. The first metal pattern has at least one first curved portion bent at one side and the second metal pattern has at least one second curved portion bent at the one side. A width of the first curved portion is greater than that of the second curved portion. A via structure is electrically connected to the second metal pattern. A third metal pattern is formed on a second metal level different from the first metal level and electrically connected to the via structure.

According to another example embodiment, a semiconductor device includes a first metal pattern formed on a first metal level. The first metal pattern has a ‘U’ shaped first curved portion. A second metal pattern is formed on the first metal level, the second metal pattern having a ‘U’ shaped second curved portion facing the first curved portion and having a width less than that of the first curved portion.

### BRIEF DESCRIPTION OF THE DRAWINGS

The above and other features and advantages of the present inventive concepts will become more apparent by describing in detail example embodiments thereof with reference to the attached drawings in which:

FIG. 1 is a diagram illustrating a semiconductor device according to an example embodiment;

FIG. 2 is a detailed layout view of a portion II of FIG. 1;

FIGS. 3 and 4 are cross-sectional views taken along the line ‘III-III’ of FIG. 2;

FIG. 5 is a layout view illustrating a semiconductor device according to another example embodiment;

FIG. 6 is a layout view illustrating a semiconductor device according to another example embodiment;

FIG. 7 is a conceptual diagram illustrating a semiconductor device according to another example embodiment;

FIG. 8 is a layout view illustrating a semiconductor device according to another example embodiment; and

FIG. 9 is a flowchart of a testing method of a semiconductor device according to an example embodiment.

### DETAILED DESCRIPTION

The inventive concepts will now be described more fully hereinafter with reference to the accompanying drawings, in which some example embodiments are shown. The inventive concepts may, however, be embodied in different forms and should not be construed as limited to the example embodiments set forth herein. Rather, these example embodiments are provided so that this disclosure will be thorough and complete, and will filly convey the scope of the inventive concepts to those skilled in the art. The same reference numbers indicate the same components throughout the specification. In the attached figures, the thickness of layers and regions is exaggerated for clarity.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation .of above and below. The device may be otherwise oriented (rotated 90 degrees or at other orientations) and the spatially relative descriptors used herein interpreted accordingly.

The use of the terms “a” and “an” and “the” and similar referents in the context of describing the invention (especially. in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or example terms provided herein is intended merely to better illuminate the inventive concepts and is not a limitation on the scope of the inventive concepts unless otherwise specified. Further, unless defined otherwise, all terms defined in generally used dictionaries may not be overly interpreted.

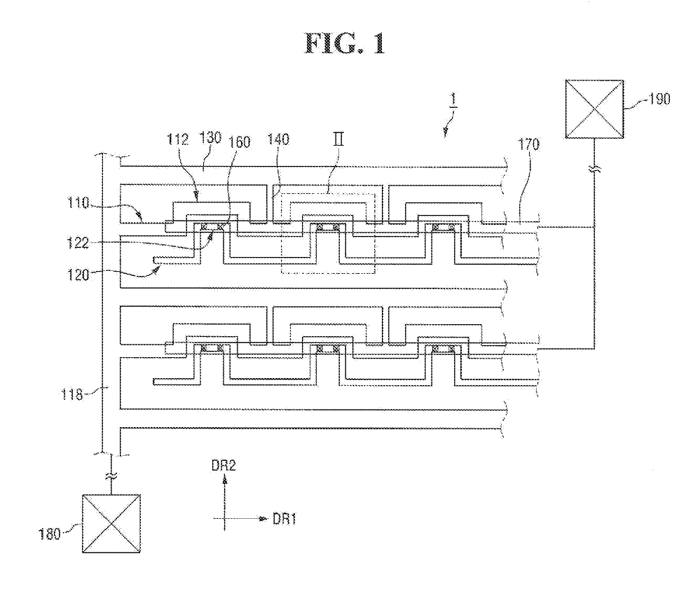

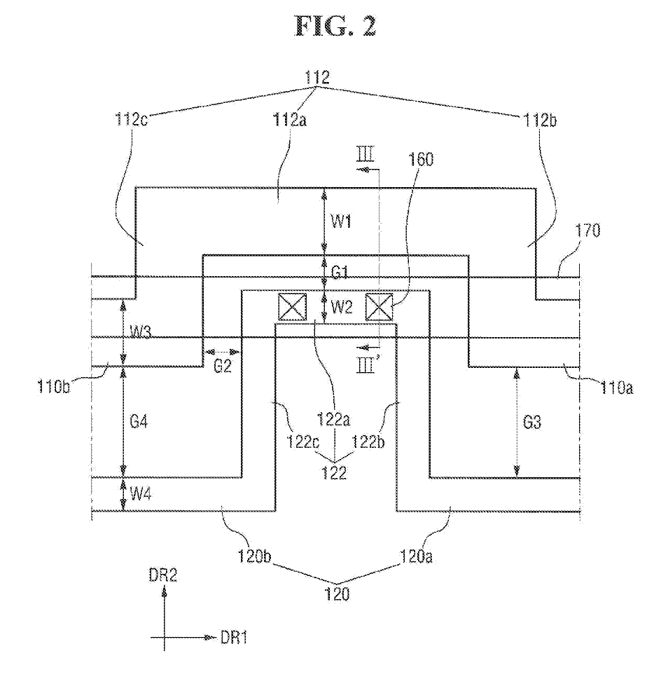

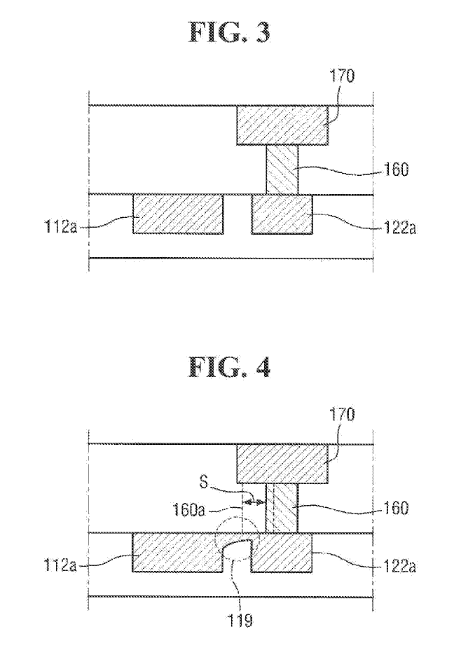

Hereinafter, a semiconductor device according to an example embodiment may be a test pattern .for determining whether a metal pattern is defective or not. FIG. 1 is a diagram illustrating a semiconductor device according to an example embodiment of the inventive concepts. FIG. 2 is a detailed layout view of a portion II of FIG. 1. FIGS. 3 and 4 are cross-sectional views taken along the line III-III′ of FIG. 2, in which FIG. 3 illustrates when the semiconductor device according to an example embodiment of the inventive concepts is in a normal state, and FIG. 4 illustrates when the semiconductor device according to an example embodiment is defective.

Referring to FIGS. 1 to 3, the semiconductor device 1 according to an example embodiment includes a first metal pattern 110, a second metal pattern 120, a via structure 160, a third metal pattern 170, a first testing pad 180, and a second testing pad 190.

The first metal pattern 110 and the second metal pattern 120 are formed on a first metal level, and the third metal pattern 170 is formed on a second metal level different from the first metal level. For example, the second metal level may be higher than the first metal level, but not limited thereto.

The first metal pattern 110 extends in a first direction DR1 and includes at least one first curved portion 112 bent in one side (for example, in a protruding shape in a second direction DR2). Specifically, the first metal pattern 110 may include a first extending pattern 110a and a second extending, pattern 110b extending in the first direction DR1 and disposed at the opposite side, of the first curved portion 112.

The first curved portion 112 may be substantially ‘U’ shaped. For example, the first curved portion 112 may include first to third parts 112a, 112b, and 112c. Specifically, the first part 112a extends in the first direction DR1, the second part 112b extends in the second direction DR2 different from the first direction DR1 and is connected to the first extending pattern 110a, and the third part 112c extends in the second direction DR2 different from the first direction DR1 and is connected to the second extending pattern 110b.

The second metal pattern 120 also extends in the first direction DR1 and includes at least one second curved portion 122 bent in one side (for example, in a protruding shape in the second direction DR2). Specifically, the second metal pattern 120 may include a third extending pattern 120a and a fourth extending pattern. 120b extending in the first direction DR1 and disposed at the opposite side of the second curved portion 122.

The second curved portion 122 may be substantially ‘U’ shaped. For example, the second curved portion 122 may include fourth to sixth parts 122a, 122b, and 122c. Specifically, the fourth part 122a extends in the first direction DR1, the fifth part 122b extends in the second direction DR2 different from the first direction DR1 and is connected to the third extending pattern 120a, and the sixth part 122c extends in the second direction DR2 different from the first direction DR1 and is connected to the fourth extending pattern 120b.

Meanwhile, the first curved portion 112 and the second curved portion 122 face each other. For example, at least a portion of the first curved portion 112 may be surrounded by at least a portion of the second curved portion 122. That is to say, at least the portion of the second curved portion 122 may be disposed in a space surrounded by the first curved portion 112.

In addition, the first curved portion 112 of the first metal pattern 110 and the second curved portion 122 of the second metal pattern 120 may be asymmetric patterns. That is to say, the at least a portion of the first curved portion 112 may be wider than the at least a portion of the second curved portion 122. For example, a width W1 of the first part 112a of the first curved portion 112 may be greater than a width W2 of the fourth part 122a of the second curved portion 122. As shown, the width W1 of the first part 112a of the first curved portion 112 may be substantially equal to a width W3 of the second extending pattern 110b, and the width W2 of the second curved portion 122 may be substantially equal to a width W4 of the fourth extending pattern 120b.

Meanwhile, a gap G3 between the first extending pattern 110a and the third extending pattern 120a is greater than gaps G1 and G2 between at least a portion of the first curved portion 112 and at least a portion of the second curved portion 122. Alternatively, a gap G4 between the second extending pattern 110b and the fourth extending pattern 120b is greater than the gaps G1 and G2 between the at least a portion of the first curved portion 112 and the at least a portion of the second curved portion 122.

In addition, the gaps G1 and G2 between the at least a portion of the first curved portion 112 and the at least a portion of the second curved portion 122 may be defined by minimum design rules. While the gaps G1 and G2 are equal to each other in the illustrated embodiment, the inventive concepts are not limited thereto. For example, only one of the gaps G1 and G2 may be defined by a minimum design rule.

The first testing pad 180 is electrically connected to the first metal pattern 110. The second testing pad 190 is electrically connected to the third metal pattern 170. Electrical signals may be supplied to the first testing pad 180 and the second testing pad 190 to determine whether the first metal pattern 110 and the second metal pattern 120 are defective or not. The testing method will later be described.

The electrical signals may be stably supplied to the first metal pattern 110 using a fourth metal pattern 130 and a connecting pattern 140. Specifically, the fourth metal pattern 130 may be disposed at one side of the first metal pattern 110, may extend in the first direction DR1 and may be electrically connected to the first metal pattern 110. Here, the fourth metal pattern 130 and the first metal pattern 110 may be connected to each other by the connecting pattern 140 extending in a second direction DR2 different from the first direction DR1. If an electrical signal is supplied to a fifth metal pattern 118, the electrical signal is transmitted to the first metal pattern 110 and the fourth metal pattern 130. Even if the first metal pattern 110 is partially cut off due to a processing failure, the electrical signal can be stably transmitted to the first metal pattern 110 using the fourth metal pattern 130 and the connecting pattern 140.

The via structure 160 is electrically connected to the second metal pattern 120. Specifically, the via structure 160 may be formed on the second curved portion 122 of the second metal pattern 120, but the inventive concepts are not limited thereto.

As shown, the via structure 160 may include two or more vias. The more the vias, the more stably the second metal pattern 120 and the second curved portion 122 can be connected to each other.

When the semiconductor device 1 according to the first, example embodiment of the present inventive concepts is in a normal state, the semiconductor device 1 may be configured as shown in FIG. 3. That is to say, the first part 112a of the first metal pattern 110 and the fourth part 122a of the second metal pattern 120 are spaced apart from each other.

Conversely, when the semiconductor device 1 according to the first embodiment of the present inventive concepts is defective, the semiconductor device 1 may be configured as shown in FIG. 4. That is to say, the first part 112a of the first metal pattern 110 and the fourth part 122a of the second metal pattern 120 are connected to each other. In other words, an abnormal short-circuit portion 119 between the first part 112a and the fourth part 122a may be generated due to various defects encountered during the manufacturing process, including, contaminants penetrating into equipment, processing errors, or the like.

As confirmed through a number of experiments conducted, when a width of the first, curved portion 112 of the first metal pattern 110 is different from that of the second curved portion 122 of the second metal pattern 120, it is highly probable that the short-circuit portion 119 will be generated. The greater the width difference between the first curved portion 112 of the first metal pattern 110 and the second curved portion 122 of the second metal pattern 120, the stronger is the possibility of generating the short-circuit portion 119. In addition, the closer the first curved portion 112 of the first metal pattern 110 and the second curved portion 122 of the second metal pattern 120 are to each other, the stronger is the possibility of generating the short-circuit portion 119.

Meanwhile, the semiconductor device 1 according to the first embodiment of the present inventive concepts can analyze in an electrical manner whether there is a defect or not (that is, whether the short-circuit portion 119 is generated or not). Specifically, as shown in FIG. 3, when the semiconductor device 1 is in a normal state, even if an electrical signal (e.g., current), is supplied to the first metal pattern 110 and the third metal pattern 170, the current may not flow between the first metal pattern 110 and the second metal pattern 120. However, as shown in FIG. 4, when the semiconductor device 1 is defective, if an electrical signal (e.g., current), is supplied to the first metal pattern 110 and the third metal pattern 170, the current may flow to the third metal pattern 170 via the first metal pattern 110 and the second metal pattern 120.

Additionally, as shown in FIG. 4, even if via structure 160a is shifted, as denoted by reference symbol S, due to various defects encountered during the manufacturing process, including contaminants penetrating into equipment, processing errors, or the like, the current may flow between the first metal pattern 110 and the second metal pattern 120.

All kinds of defects may be detected through an optical test. However, major defects directly affecting a reduction in the yield cannot be analyzed by the optical test. In addition, the equipment for use in an optical test may perform a test on a semiconductor wafer by a scanning method, which is time-consuming. Therefore, the optical test cannot be carried out on every semiconductor wafer in the manufacturing process. The optical test may be carried out on a particular region of a semiconductor wafer. In this case, however, it is not possible to detect all defects of the semiconductor wafer, restricting, improvement of the yield. However, the semiconductor device 1 according to the example embodiment can detect defects accurately within a shorter time, enabling improvement of the yield.

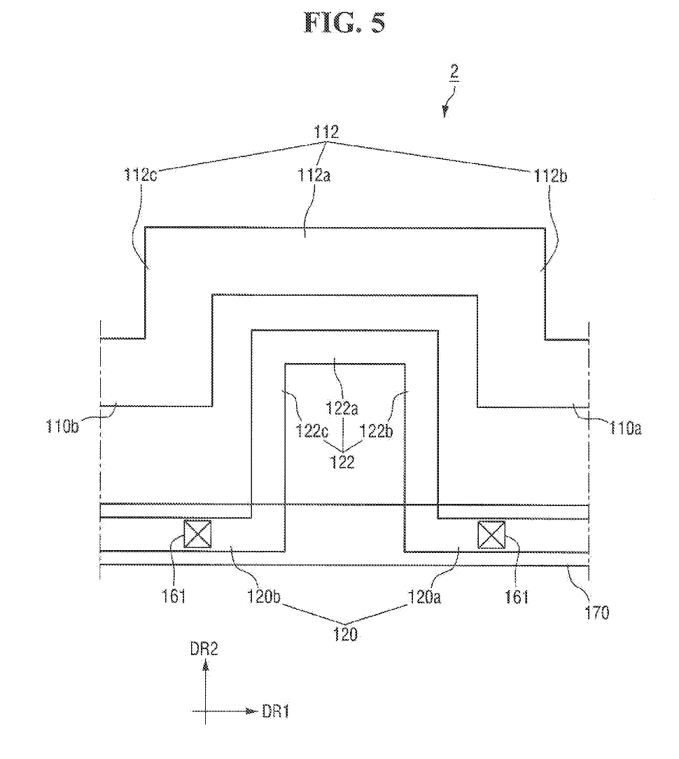

FIG. 5 is a layout view illustrating a semiconductor device according to another example embodiment. The semiconductor device 2 according to the example embodiment of FIG. 5 is different from the semiconductor device 1 according to an example embodiment illustrated in FIG. 1 in that a via structure 161 is disposed on third and fourth extending patterns 120a and 120b of a second metal pattern 120. A third metal pattern 170 may be disposed to overlap with the third and fourth extending patterns 120a and 120b according to the positional change of the via structure 161.

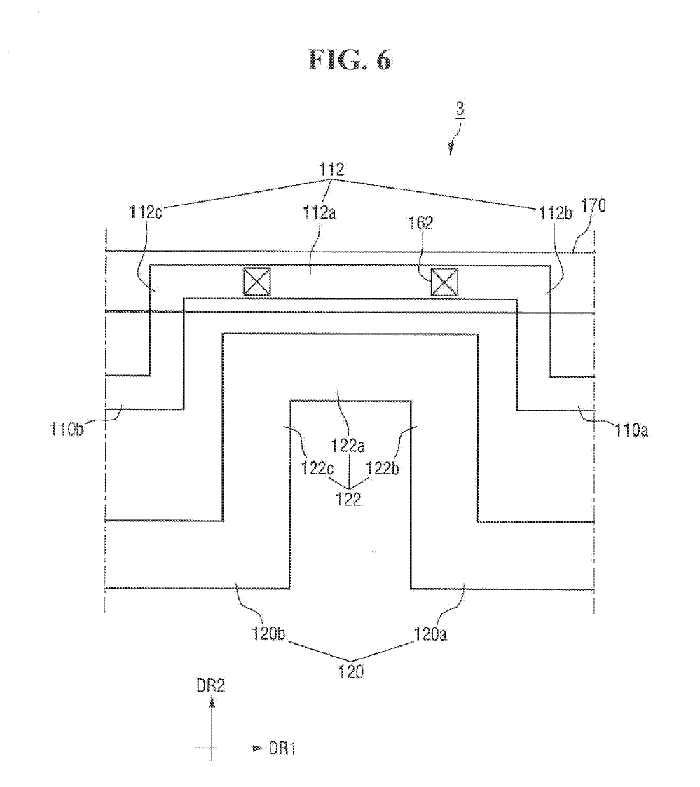

FIG. 6 is a layout view illustrating a semiconductor device according to another example embodiment. The semiconductor device 3 according to the example embodiment of FIG. 1 is different from the semiconductor device 1 as illustrated in FIG. 1 in that at least a portion of a first curved portion 112 of a first metal pattern (1_1) 110 has a width smaller than that of at least a portion of a second curved portion 122 of a second metal pattern (1_2) 120. As described above, the first curved portion 112 and the second curved portion 122 have different widths, a short-circuit portion (119 of FIG. 4) may be generated.

In addition. a via structure 162 is disposed on a first curved portion 112 of a first metal pattern 110. A third metal pattern 170 may be disposed to overlap with the first curved portion 112 according to the positional change of the via structure 162.

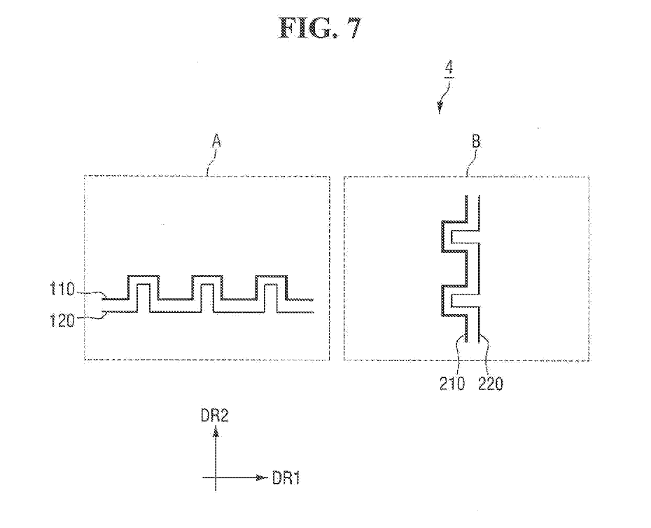

FIG. 7 is a conceptual diagram illustrating a semiconductor device according to another example embodiment. The semiconductor device 4 according to the example embodiment includes a first region A and a second region B.

In the first region A are formed a first metal pattern (1_1) 110 and a second metal pattern (1_2) 120 formed on a first metal level and extending in a first direction DR1. As described above, a first curved portion of the first metal pattern 110 and a second curved portion of the second metal pattern 120 may face each other, and at least a portion of the first curved portion may have a width greater than that of at least a portion of the second curved portion. The first curved portion surrounds a portion of the second curved portion. Although not shown, a third metal pattern formed on a second metal level and electrically connected to the first metal pattern 110 or the second metal pattern 120 may be formed. The first metal pattern 110 is connected to a first testing pad and the third metal pattern is connected to a second testing pad.

In the second region B are formed a first metal pattern (1_1) 210 and a second metal pattern (1_2) 220 formed on the first metal level and extending in a second direction DR2 different from the first direction DR1. As described above, a first curved portion of the first metal pattern 210 and a second curved portion of the second metal pattern 220 may face each other, and at least a portion of the first curved portion may have a width greater than that of at least a portion of the second curved portion. The first curved portion surrounds a portion of the second curved portion.

According to an example embodiment, determining, in which direction the semiconductor device 4 is defected is possible using the first metal patterns 110 and 210 and the second metal patterns 120 and 220, which are disposed in different directions.

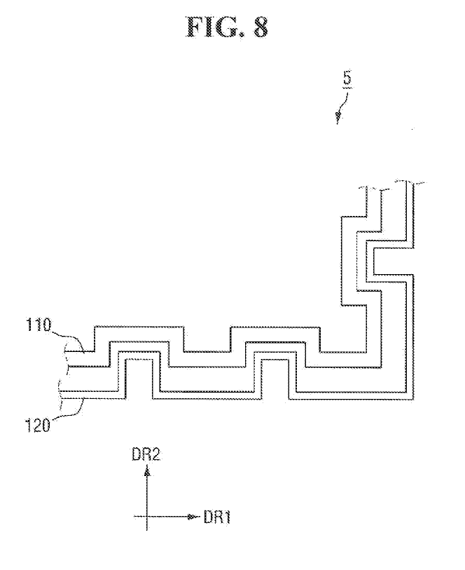

FIG. 8 is a layout view illustrating a semiconductor device according to another example embodiment. The semiconductor device 5 according to the example embodiment illustrated in FIG. 8 includes a first metal pattern (1_1) 110 and a second metal pattern (1_2) 120 extending in a first direction DR1 and bent and extending in a second direction DR2. According to the example embodiment, determining a defect generated in any direction is possible using the first and second metal patterns 110 and 120, which are bent and extend.

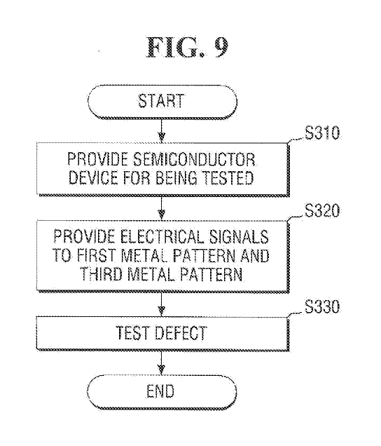

FIG. 9 is a flowchart of a testing method of a semiconductor device according to an example embodiment. Referring to FIG. 9, a semiconductor device according to the example embodiment (for example, the semiconductor device 1 as illustrated in FIG. 1) is provided (S310). As described above, the semiconductor device 1 may include a first metal pattern (1_1) 110 formed on a first metal level and having a U-shaped first curved portion 112, a second metal pattern (1_2) 120 having a U-shaped second curved portion 122 facing the first curved portion 112, a via structure 160 electrically connected to the second metal pattern 120, and a third metal pattern 170 formed on a second metal level different from the first metal level and electrically connected to the via structure 160.

Electrical signals are supplied to the first metal pattern 110 and the third metal pattern 170 (S320). The first metal pattern 110 and the second metal pattern 120 are tested to determine whether the semiconductor device 1 is defective or not (S330). An amount of current flowing between the first metal pattern 110 and the third metal pattern 170 is measured to determine whether the semiconductor device 1 is defective or not. For example, if no current flows between the first metal pattern 110 and the third metal pattern 170, the semiconductor device 1 is determined to be normal. If current flows between the first metal. pattern 110 and the third metal pattern. 170, the semiconductor device I is determined to be defective.

While the present inventive concepts have been particularly shown and described with reference to example embodiments thereof, it will be understood by those of ordinary skill in the art that various changes in form and details may be made therein without departing from the spirit and scope of the following claims. It is therefore desired that example embodiments be considered in all respects as illustrative and not restrictive, reference being made to the appended claims rather than the foregoing description to indicate the scope of the inventive concepts.

What is claimed is:

1. A semiconductor device comprising:
a first metal pattern formed on a first metal level, the first metal pattern having a ‘U’ shaped first curved portion;
a second metal pattern formed on the first metal level, the second metal pattern having a ‘U’ shaped second curved portion facing the first curved portion;
a via structure electrically connected to one of the first metal pattern and the second metal pattern; and
a third metal pattern formed on a second metal level different from the first metal level and electrically connected to the via structure.

2. The semiconductor device of claim 1, wherein at least a portion of the first curved portion is wider than at least a portion of the second curved portion.

3. The semiconductor device of claim 1, wherein the first curved portion surrounds a portion of the second curved portion.

4. The semiconductor device of claim 1, wherein a gap between at least a portion of the first curved portion and at least a portion of the second curved portion is defined by a minimum design rule.

5. The semiconductor device of claim 4, wherein
the first metal pattern extends in a first direction and includes a first extending pattern and a second extending pattern disposed at opposite sides of the first curved portion, and
the second metal pattern extends in the first direction and includes a third extending pattern and a fourth extending pattern disposed at opposite sides of the second curved portion.

6. The semiconductor device of claim 5, wherein a gap between the first extending pattern and the third extending pattern is greater than that between the first curved portion and the second curved portion.

7. The semiconductor device of claim 5, further comprising:
a fourth metal pattern disposed at one side of the first metal pattern, extending in the first direction and electrically connected to the first metal pattern.

8. The semiconductor device of claim 7, wherein the fourth metal pattern and the first metal pattern are connected to each other by a connecting pattern extending in a second direction different from the first direction.

9. The semiconductor device of claim 1, wherein the via structure is formed on the first curved portion of the first metal pattern or on the second curved portion of the second metal pattern.

10. The semiconductor device of claim 1, wherein the via structure is electrically connected to the second metal pattern, and includes a first testing pad electrically connected to the first metal pattern and a second testing pad electrically connected to the third metal pattern.

11. The semiconductor device of claim I, wherein the via structure includes two or more vias.

12. A semiconductor device comprising:
first and second metal patterns formed on a first metal level, the first metal pattern having at least one first curved portion bent at one side and the second metal pattern having at least one second curved portion bent at the one side, and a width of the first curved portion being greater than that of the second curved portion;
a via structure electrically connected to the second metal pattern; and
a third metal pattern formed on a second metal level different from the first metal level and electrically connected to the via structure.

13. The semiconductor device of claim 12, wherein the first curved portion surrounds a portion of the second curved portion.

14. The semiconductor device of claim 12, wherein a gap between at least a portion of the first curved portion and at least a portion of the second curved portion is defined by a minimum design rule.

15. The semiconductor device of claim 12, wherein
the first metal pattern includes a first extending pattern and a second extending pattern disposed at opposite sides of the first curved portion, and a third extending pattern and a fourth extending pattern disposed at opposite sides of the second curved portion, and
a gap between the first extending pattern and the third extending pattern is greater than that between the first curved portion and the second curved portion.

16. The semiconductor device of claim 12, further comprising:
a fourth metal pattern disposed at one side of the first metal pattern, extending in the first direction and electrically connected to the first metal pattern,
wherein the fourth metal pattern and the first metal pattern are connected to each other by a connecting pattern extending in a second direction different from the first direction.

17. The semiconductor device of claim 12, further comprising:
a first testing pad electrically connected to the first metal pattern and a second testing pad electrically connected to the third metal pattern.

18. A semiconductor device comprising:
a first metal pattern formed on a first metal level, the first metal pattern having a ‘U’ shaped first curved portion;
a second metal pattern formed on the first metal level, the second metal pattern having a ‘U’ shaped second curved portion facing the first curved portion and having a width less than that of the first curved portion.

19. The semiconductor device of claim 18, further comprising:
a via structure electrically connected to one of the first metal pattern and the second metal pattern; and
a third metal pattern formed on a second metal level different from the first metal level and electrically connected to the via structure.

20. The semiconductor device of claim 18, wherein the first curved portion surrounds a portion of the second curved portion.
